(19) United States
(12) Patent Application Publication
(10) Pub. No.: US 2008/0111642 A1
(43) Pub. Date: May 15, 2008

(54) APPARATUS AND METHODS FOR VCO LINEARIZATION

(76) Inventor: Jose Bohorquez, Cambridge, MA (US)

Correspondence Address: LOWRIE, LANDO & ANASTASI, LLP, ONE MAIN STREET, SUITE 1100, CAMBRIDGE, MA, 02142, US

(21) Appl. No.: 11/558,254

(22) Filed: Nov. 9, 2006

(51) Int. Cl. H03B 5/12

(52) U.S. Cl. 331/117 FE; 331/177 V

(57) ABSTRACT

A method of linearizing a frequency versus tuning voltage response of a voltage controlled oscillator comprising multiple varactor sets. In one example, a the method of linearizing includes acts of providing a first varactor set with a first bias voltage, providing a second varactor set with a second bias voltage, and adjusting the first and second bias voltages so as to linearize the frequency versus tuning voltage response of the voltage controlled oscillator over a selected operating frequency range of the voltage controlled oscillator. The method can be extended to N varactor sets and can be applied to many RF CMOS or analog CMOS components, including voltage controlled oscillators.

### BACKGROUND

1. Field of Invention

The present invention is directed to devices, such as voltage controlled oscillators, having tunable elements and methods for linearizing the tuning response of such devices.

2. Discussion of Related Art

In a wireless transceiver, voltage controlled oscillators (VCOs) are typically employed as part of the frequency synthesizer (FS) to generate a range of operating frequencies. The VCO is generally tunable within a given frequency range to allow selection of a center operating frequency for the frequency synthesizer. A common configuration for a VCO is that of a tunable resonant circuit, such as an inductive-capacitive (LC) resonant circuit, which may be tuned via adjustable inductive or capacitive elements. One example of an adjustable capacitive element that can be used to tune the resonant circuit to a desired operating center frequency is a varactor.

A varactor may operate as a voltage-controlled capacitor. There are generally three types of approaches to implementing varactors in CMOS (complementary metal oxide semiconductor) technology: reverse-biased pn-junction diodes, depletion mode MOS capacitors, and accumulation mode MOS capacitors. Varactor diodes are typically operated reverse-biased so no current flows, but since the width of the depletion zone varies with the applied bias voltage, the capacitance of the diode can be made to vary. Of the three above-mentioned varactors, the accumulation mode MOS (aMOS) varactor can be fabricated to have the best combination of quality factor (Q) and tuning range. However, the aMOS varactor has the disadvantage of poor linearity, which is undesirable in many cases. For example, poor linearity in the varactor results in increased non-linearity in the tuning response of the VCO.

In a publication by C. R. C. De Ranter, and M. S. J. Steyaert entitled “A 0.25 μm CMOS 17 GHz VCO,” (Solid-State Circuits Conference, 2001, ISSCC 2001, IEEE International, pp. 370-371, February 2001, and herein incorporated by reference) details of a voltage controlled oscillator layout, including a varactor diode for tuning, are disclosed. Another article by P. Andreani and S. Mattisson entitled “On the Use of MOS Varactors in RF VCO's” (and published in IEEE Journal of Solid-State Circuits, vol. 35, pp. 905-910, June 2000 and herein incorporated by reference) discusses various varactor types, namely accumulation mode, inversion mode, and diode, that can be used as part of a tunable tank circuit for a VCO. In this article, the authors shown that that the aMOS varactor displays the best performance in their experiments.

There are several examples of approaches designed to linearize VCO responses with tunable elements. For example, U.S. Pat. No. 5,014,021 to Robertson, Jr. et al. (which is herein incorporated by reference) discloses the use of a radial line, (top-hat) disc geometry in conjunction with a varactor diode disposed in a broadband, ridged waveguide oscillator circuit to produce a frequency-linearized voltage controlled oscillator. According to the '021 patent, a disc resonator in a ridged waveguide is used to transform the microwave impedance of a non-RF generating element, a varactor diode, to values which provide improved voltage controlled oscillator tuning linearity. The disc resonator or radial line is located above the varactor diode and transforms the microwave impedance of the varactor diode to a new value which is then coupled into the ridged waveguide circuit and subsequently to the RF generating diode. The circuit impedance, which is a function of the varactor voltage, acts to linearize the frequency versus voltage characteristic of the diode.

An example of a fabrication technique designed to enhance the quality factor and tunability of a CMOS varactor is disclosed in U.S. Patent Application 2006/0043454, which is herein incorporated by reference. Other examples of fabrication techniques for CMOS varactors are disclosed, for example, in U.S. Patent Applications 2006/0006431 and 2005/0253660, each of which are herein incorporated by reference. These examples discuss various methods for fabricating varactors in CMOS technology with an eye toward improving the linearity of the varactor. However, none of the references discuss how various given varactors can be arranged so as to linearize the frequency response of a VCO in which they are used.

### SUMMARY OF INVENTION

Aspects and embodiments of the invention are directed to a system and methods for linearizing the response of a component, such as voltage controlled oscillator or other CMOS component, that includes one or more sets of varactors. In one embodiment, a component may include two or more sets of varactors that share a common tuning voltage, each varactor set having an individual bias voltage. The individual bias voltages may be selected so as to linearize a frequency versus tuning voltage response of a resonant circuit that includes the varactor sets. It is to be appreciated that, as used herein, the use of the term “each” (for example, “each varactor set”) is intended to refer to individual elements, but is not intended to be equivalent to “all” or to require that every element have the feature being described.

According to one embodiment, a tunable voltage controlled oscillator may comprise a first varactor set comprising at least one CMOS varactor, a second varactor set comprising at least one CMOS varactor and coupled in parallel with the first varactor set, a first bias voltage applied to the first varactor set, and a second bias voltage applied to the second varactor set, wherein the first and second bias voltages are selected such that a frequency versus tuning voltage of the voltage controlled oscillator is substantially linear over a selected operating frequency range of the voltage controlled oscillator. The CMOS varactors may include, for example, accumulation mode MOS capacitors, depletion mode MOS capacitors or reverse-biased pn-junction diodes. In one example, the tunable voltage controlled oscillator may further comprise a third varactor set and a third bias voltage applied to the third varactor set, wherein the first, second and third bias voltages are selected such that the frequency versus tuning voltage of the voltage controlled oscillator is substantially linear over the selected operating frequency range of the voltage controlled oscillator.

According to another embodiment, there is provided a method of linearizing a frequency versus tuning voltage response of a voltage controlled oscillator comprising a first varactor set and a second varactor set. The method may comprise acts of providing the first varactor set with a first bias voltage, providing the second varactor set with a second bias voltage, and adjusting the first and second bias voltages so as to linearize the frequency versus tuning voltage response of the voltage controlled oscillator over a selected operating frequency range of the voltage controlled oscillator. In one example, the method may further comprise an act of providing the first and second varactor sets with a common tuning voltage. In another example, the voltage controlled oscillator may further include a third varactor set, and the method may further comprise an act of providing a third bias voltage to the third varactor set, wherein the act of adjusting includes adjusting the first, second and third bias voltages so as to linearize the frequency versus tuning voltage of the voltage controlled oscillator over the selected operating frequency range of the voltage controlled oscillator. In another example, the act of adjusting may include adjusting the first, second and third bias voltages such that the frequency versus tuning voltage response of the voltage controlled oscillator is substantially linear over the selected operating frequency range of the voltage controlled oscillator.

Another embodiment of a voltage controlled oscillator may comprise a tunable resonant circuit including at least one inductor, a first set of varactors and a second set of varactors, the first and second sets of varactors being connected in parallel with one another, a tuning port constructed and arranged to receive a tuning voltage, a first port coupled to the first varactor set and constructed and arranged to receive a first bias voltage, and a second port coupled to the second varactor set and constructed and arranged to receive a second bias voltage, wherein the first and second bias voltages are selected such that an operating frequency of the voltage controlled oscillator changes in a substantially linear manner in response to changes in the tuning voltage. In one example, the first and second varactor sets may each comprise at least one CMOS accumulation mode or depletion mode capacitor.

### BRIEF DESCRIPTION OF THE DRAWINGS

Aspects and embodiments of the invention are described in detail below with reference to the accompanying drawings. It is to be appreciated that the drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a diagram of one embodiment of a voltage controlled oscillator;

FIG. 2 is an plot of the frequency tuning response as a function of tuning voltage and the tuning sensitivity as a function of tuning voltage for a voltage controlled oscillator.

FIG. 3 is a diagram of one example of a voltage controlled oscillator including two varactor sets, according to one embodiment of the invention;

FIG. 4 is a plot of frequency tuning responses versus tuning voltage for a single varactor set, two varactor sets in parallel, and three varactor sets in parallel;

FIG. 5 is a diagram of one example of a VCO including n varactor sets, according to an embodiment of the invention;

FIG. 6a is a plot of a measured VCO frequency tuning response as a function of tuning voltage for a VCO including one varactor set;

FIG. 6b is a plot of measured VCO tuning sensitivity as a function of tuning voltage for the VCO including one varactor set;

FIG. 7a is a plot of a measured VCO frequency tuning response versus tuning voltage for a VCO including three varactor sets in parallel, in accordance with an embodiment of the invention; and

FIG. 7b) is a plot of the tuning sensitivity as a function of tuning voltage for the VCO including three varactor sets in parallel, according to one embodiment of the invention.

### DETAILED DESCRIPTION

The need for a frequency synthesizer to operate over a wide band of frequencies may be particularly important when implementing multi-band, multi-mode transceiver architectures. These architectures may be designed to accommodate various frequency bands and modes for today's different communication standards and protocols such as, for example, GSM (Groupe Special Mobile), CDMA (Code Division Multiple Access), CDMA2k (Code Division Multiple Access 2000), UMTS (Universal Mobil Telecommunications Systems), IEEE 802.11a/b/g, and the like. Therefore, the voltage controlled oscillator (VCO), as part of the frequency synthesizer, preferably should have a sufficiently large tuning range to cover the desired frequency span, including process and temperature variations.

Accordingly, aspects and embodiments of the invention are directed to a system and method for linearizing the tuning response of a voltage controlled oscillator (VCO) that may be used as part of a frequency synthesizer for a multi-band, multi-mode transceiver. However, it is to be appreciated that the embodiments described herein are not limited to use in a transceiver and may be applied to a variety of circuits and devices. In addition, embodiments of varactor linearization techniques described below may also be used in other radio frequency (RF) CMOS and analog CMOS components, and are not limited to voltage controlled oscillators. It is also to be appreciated that this invention is not limited in its application to the details of construction and the arrangement of components set forth in the following description or illustrated in the drawings. The invention is capable of other embodiments and of being practiced or of being carried out in various ways, and the invention is not limited to the examples presented unless specifically recited in the claims. In addition, it is to be appreciated that the phraseology and terminology used herein is for the purpose of description and should not be regarded as limiting. The use of the words “including,” “comprising,” “having,” “containing,” or “involving,” and variations thereof herein, is meant to encompass the items listed thereafter and equivalents thereof as well as additional items.

According to one embodiment, a VCO may include a tunable inductive-capacitive (LC) resonant circuit that provides an output signal, referred to herein as f_{VCO}, having a center resonance frequency and a certain bandwidth. Tunability of the resonant circuit, and thus the VCO, may be provided by one or more switchable capacitors that can be switched in and out of the resonant circuit, as well as one or more variable capacitors (varactors). Examples of embodiments of such VCOs are described in commonly-owned, copending U.S. patent applications (insert serial number 700219) and (insert serial number 700319), which are herein incorporated by reference.

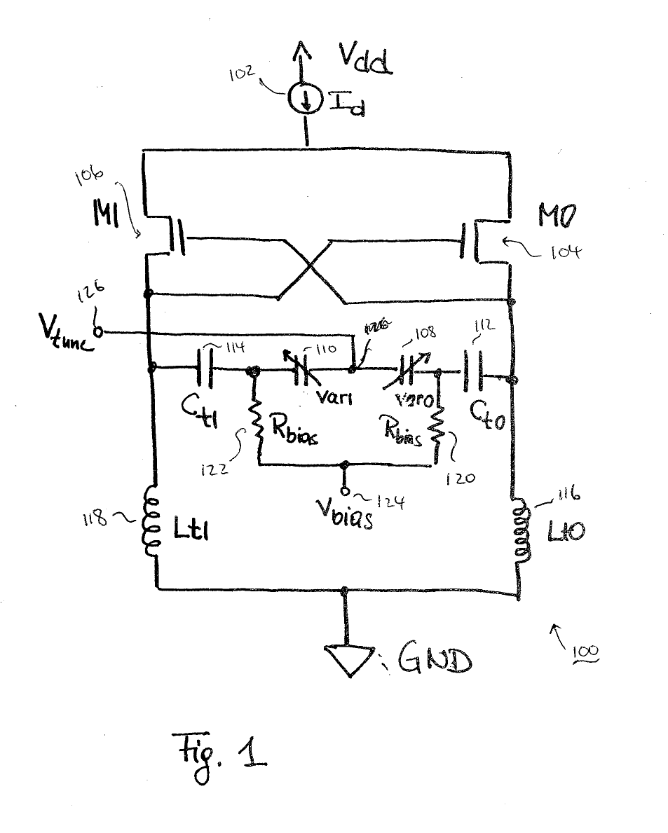

Referring to FIG. 1, there is illustrated one embodiment of a varactor-tuned VCO according to embodiments of the invention. The VCO 100 may include a current source 102 that provides current I_{d}, and two cross-coupled CMOS field effect transistors 104, 106. The transistors are connected a varactor set comprising at least two varactors 108, 110 via coupling capacitors 112, 114 respectively, as shown in FIG. 1. Inductors 116 and 118 may be connected in parallel with the varactors 108 and 110 to provide a resonant circuit. It is to be appreciated that the VCO resonant circuit may also include a plurality of switchable capacitors (not shown) as discussed above. The varactor set provides a capacitance C and the coupling capacitors 112 and 114 provide capacitances Cₜ₀ and Cₜ₁, respectively. The combined capacitance from the varactor set, and the coupling capacitors (and also from any switchable capacitors that may be switched in to the resonant circuit), along with the inductances Lₜ₀ and Lₜ₁ provided by the inductors 116 and 118, respectively, may be chosen to achieve a desired resonant center frequency for the VCO. In one embodiment, the capacitance values of the coupling capacitors and the inductance values of the inductors may be fixed and thus tunability of the center resonant frequency may be achieved by varying the capacitance C provided by the varactor set, as discussed further below.

Referring again to FIG. 1, bias resistors 120 and 122 may be used to couple varactors 108 and 110, respectively, to a bias voltage port 124. A bias voltage v_{bias} may be applied to the varactors via the bias voltage port 124. The varactors may also be coupled to a tuning voltage port 126 to which a tuning voltage vₜᵤₙₑ may be applied. The tuning voltage and the bias voltage may be used to vary the capacitance of the varactors, as discussed further below.

The variable capacitance C, as a function of the tuning voltage, of the varactor set may be described by the equation:

$$C ( {v}_{tune} ) = {C}_{0} + {C}_{1} tanh ( \frac{{v}_{tune} - {v}_{bias}}{{v}_{1}} ) \qquad ( 1 )$$

where νₜᵤₙₑ is the externally applied tuning voltage and ν_{bias} is the bias voltage applied at the bias voltage port 124. Capacitances C₀ (from varactor 108) and C₁ (from varactor 110) may be determined by the geometry of the CMOS varactors and by the underlying semiconductor fabrication process. It is to be appreciated that in embodiments where the varactor set comprises more than two varactors, the variable capacitance of the varactor set given by equation (1) will include additional capacitances Cₙ corresponding to the additional varactors in the varactor set. The capacitances C₀ and C₁ are generally not completely independent from one another. The sharpness constant v₁ is a device parameter that may be determined by the underlying semiconductor fabrication process. The sensitivity of the variable capacitance to changes in the tuning voltage can be expressed as the derivative of equation (1) with respect to the tuning voltage. Thus, the sensitivity, Kv, is given by:

$$Kv = \frac{\partial C ( {v}_{tune} )}{\partial {v}_{tune}} \qquad ( 2 )$$

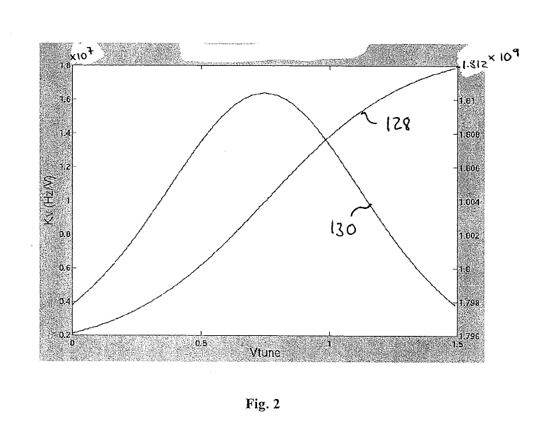

Referring to FIG. 2, there is illustrated a graph of a simulation of both C and Kv as a function of the tuning voltage. The tuning voltage is represented on the horizontal axis in units of Volts (V) and varies between zero and 1.5 V. Line 128 represents C and line 130 represents Kv. For these simulations, a fixed bias voltage of 0.75 V and a voltage sharpness constant of v₁=0.55 V were used. However, it is to be appreciated that other fixed and/or variable parameter constants may be selected depending, for example, on the device geometry and microelectronic fabrication process. It can be seen from FIG. 2 that the tuning sensitivity (line 130) is highly non-linear, having a variation ratio of about 4:1, over the selected range of tuning voltages. Such non-linearity may be very undesirable in many applications. For example, the loop bandwidth of a frequency synthesizer may be dependent on the tuning sensitivity (Kv) of the VCO. If this tuning sensitivity curve is highly nonlinear, as in FIG. 2, the loop bandwidth may be dramatically different depending on the point on the tuning curve in which the VCO is locked. Another application in which this nonlinearity is highly undesirable is in direct modulation techniques for digital data transmission in which the VCO is phase or frequency modulated through a tuning port. In this case, nonlinearities in the VCO frequency tuning may result in distortion which increases the error vector magnitude (EVM) of the digital data transmission.

To overcome the aforementioned shortcomings, a technique may be desired that may greatly improve the linearity of accumulation mode varactors, resulting in a more linear VCO frequency response as a function of tuning voltage. Ideally, implementation of such a technique should not include any additional processing steps or costs.

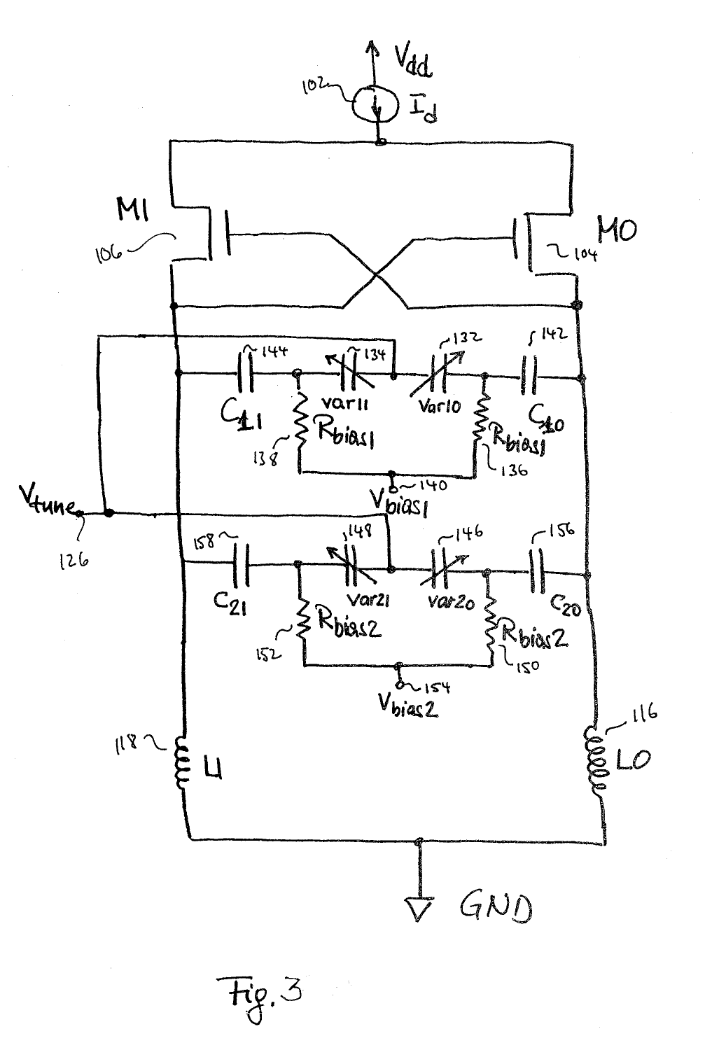

According to one embodiment, there is provided and arrangement of multiple varactor sets in parallel, each set receiving a different bias voltage, while maintaining the same tuning voltage for all sets. Instead of using one varactor set biased at the midpoint of the tuning curve, as is conventionally done, two or more varactor sets may be connected in parallel, each receiving its own, distinct bias voltage. For example, referring to FIG. 3, there is illustrated one embodiment of a VCO, similar to that illustrated in FIG. 1, but comprising two varactor sets. The first varactor set comprises two varactors 132 and 134 with associated bias resistors 136 and 138, respectively, via which the two varactors 132 and 134 are coupled to a first bias voltage port 140. Coupling capacitors 142 and 144 couple the varactors to the MOS transistors 104 and 106, as shown. The second varactor set also comprises two varactors 146 and 148 with associated bias resistors 150 and 152, respectively, via which the varactors are coupled to a second bias voltage port 154. Coupling capacitors 156 and 158 couple the varactors 146 and 148 to the MOS transistors, as shown.

By supplying the bias ports with different voltages, ν_{biasn} (where n=1, 2, etc., and corresponds to number of the varactor set to which the nth bias voltage is supplied), a superposition of the individual capacitance responses of the varactor sets can be obtained such that the resulting overall capacitance may approach a flat response. As a result, the VCO frequency behavior may be linearized over a wide range of tuning voltages. Each varactor set may be coupled to a common tuning voltage port 126 to receive the tuning voltage, νₜᵤₙₑ, to receive a common tuning voltage.

According to one embodiment, a procedure for determining appropriate values of ν_{biasn} (n=1, 2, . . . ) can be developed by setting to zero the derivative of the combined capacitance with respect to νₜᵤₙₑ and theoretically finding the values of ν_{biasn}. In other words, the combined tuning sensitivity Kv may be set to zero, corresponding to an ideal case in which the tuning sensitivity does not vary with the tuning voltage. Mathematically, this may be stated as

$$\frac{d {C}_{total} ( {v}_{tune} )}{d {v}_{tune}} = 0 \qquad ( 3 )$$

where Cₜₒₜₐₗ(vₜᵤₙₑ) denotes the total capacitance provided by the sum of the parallel-connected individual varactor sets. Alternatively, one can select the bias voltages through trial-and-error and by using a circuit simulator. For example, the circuit simulator may be used to represent the VCO circuit, for example, the circuit as shown in FIG. 3, and an initial set of bias voltages may be selected and input to the circuit simulator. The capacitive response of the circuit may then be calculated by the circuit simulator. The bias voltages may be iteratively adjusted the capacitive response becomes flat, or nearly flat within acceptable design tolerances.

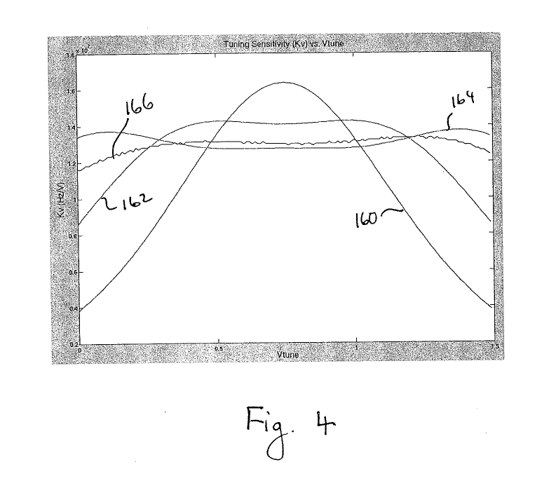

Referring to FIG. 4, there is illustrated a theoretical tuning sensitivity (as a function of tuning voltage) for a VCO using several different varactor sets. The tuning voltage is represented on the horizontal axis in units of Volts, and ranges from 0 to 1.5 V. Tuning sensitivity, Kv, is represented on the vertical axis. Line 160 represents the tuning sensitivity versus tuning voltage for a VCO with one varactor set. As was the case in FIG. 2, this response is highly non-linear over the tuning voltage range. Line 162 represents the tuning sensitivity of a VCO comprising two varactor sets, as illustrated in FIG. 3. Although still non-linear over the tuning voltage range, it can be seen that line 162 has less variation than does line 160. Line 164 represents the tuning sensitivity of a VCO including three varactor sets, which is seen to be relatively flat or linear over the tuning voltage range. These simulations were obtained using simple MATLAB models of ideal components. For the simulation of the case in which the VCO comprised two varactor sets (line 162), the bias voltages for the two varactor sets were selected to be v_{bias1}=0.35V and v_{bias2}=1.15V. For the simulation of the VCO circuit including three varactor sets, the bias voltage values were selected to be v_{bias1}=0V, v_{bias2}=0.75V, and v_{bias3}=1.5V. It is to be appreciated that other bias voltage values may yield different responses. In addition, these results were obtained using ideal circuit simulations, and actual measured responses are therefore expected to be somewhat different. However, the simulations serve to illustrate that by using two or more parallel-connected varactor sets, rather than a single varactor set, the tuning sensitivity may be greatly linearized.

Also shown in FIG. 4 is line 166 which represents the results of a circuit simulation of a VCO having three varactor sets. The simulation was produced using Cadence's Spectre simulator. Realistic, rather than simple ideal, component models of the underlying microelectronic fabrication process were used to model the VCO. In this example, the model was based on a 130 nanometer (nm) United Microelectronics Corporation (UMC) fabrication process. The component models were obtained by electrically characterizing the fabrication process through on-wafer measurements and then creating electric equivalent circuits, as known to those skilled in the art. As can be seen in FIG. 4, line 166 resembles line 164 (from the ideal model of a VCO with three varactor sets), but includes slightly more variation. The simulation illustrates the linearization of tuning sensitivity that may occur by using several parallel-connected sets of varactors.

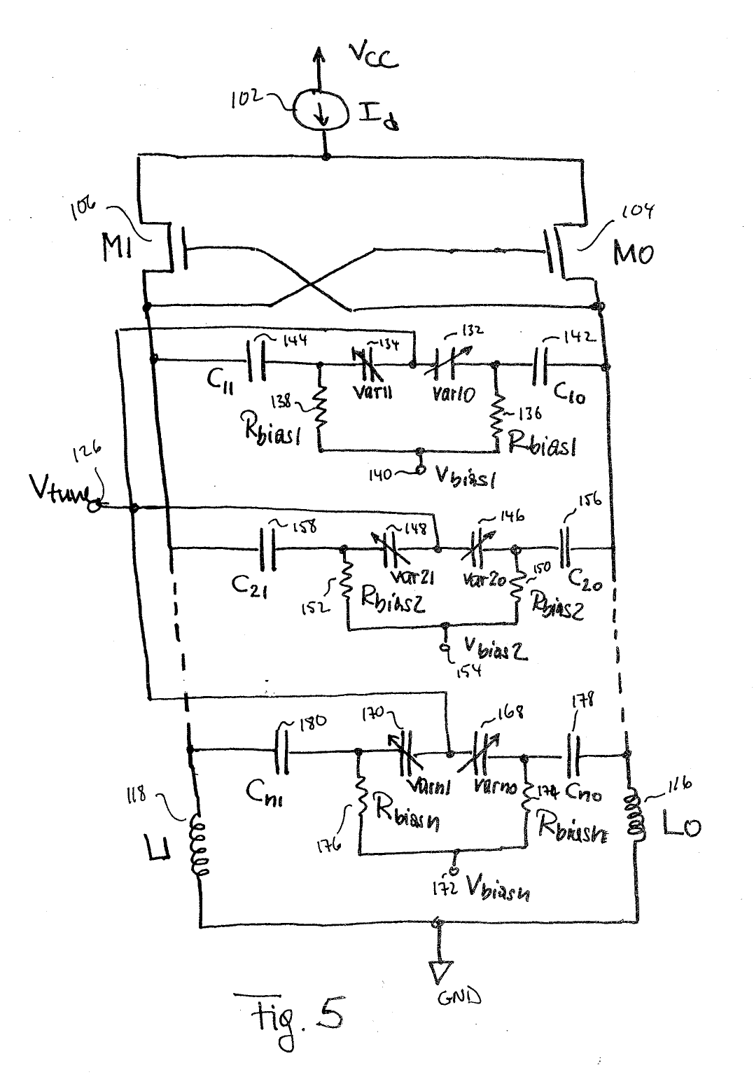

Referring to FIG. 5, there is illustrated a circuit diagram extending the circuit shown in FIG. 3 to n varactor sets, wherein n is any integer. In FIG. 4, it can be seen that the current source 102 and the transistor pair (M0, M1) 104, 106 may be connected to the first varactor set, denoted by var10 (varactor 132) and var11 (varactor 134), as also shown in FIG. 3. The first varactor set is connected to the first bias voltage port 140, where a first bias voltage ν_{bias1} is provided, through bulk bias resistors 136 and 138 having a value of R_{bias1}. Additionally, coupling capacitors C10 and C11 connect the first varactor set in parallel with a second varactor set, denoted by var20 (varactor 146) and var21 (varactor 148) and having its own coupling capacitors 156 (C20) and 158 (C21). The bias voltage ν_{bias2} is provided from bias voltage port 154 via bias resistors 150 and 152 (having a value R_{bias2}) to the second varactor set. Similarly, the nth varactor set may include varactors 168 (varn0) and 170 (varn1) coupled to an nth bias voltage port 172 via bias resistors 174 and 176 (having a value R_{biasn}). Coupling capacitors 178 and 180 may be provided to couple the nth varactor set to the MOS transistors in parallel with the other varactor sets, as discussed with reference to FIG. 3.

As discussed above, if n=2 and one sets, for example, by trial and error, ν_{bias1}=0.35 V and ν_{bias2}=1.15 V, in a simulation using idealized component models, one obtains line 162 in FIG. 4. In one embodiment, typical voltage ranges for the bias voltage may be from zero Volts to the supply voltage, which for the 130 nm UMC fabrication process is usually 1.5 V. Increasing the number of varactor sets, and allowing each set to have a tailored bias voltage, may allow for a higher degree of linearization. This is shown in FIG. 3, where the sensitivity plot of a VCO with three varactor sets (line 164) is more linear over the tuning range than is the sensitivity plot of a VCO with two varactor sets (line 162). In one example, different bias voltages may be generated on the semiconductor chip (of which the VCO may be a part) and supplied to the bias voltage ports. Alternatively, in another example, a common voltage (e.g., the supply voltage) may be applied to each of the bias voltage ports and the values of the bias resistors may be selected to apply the different desired bias voltages to the different varactor sets.

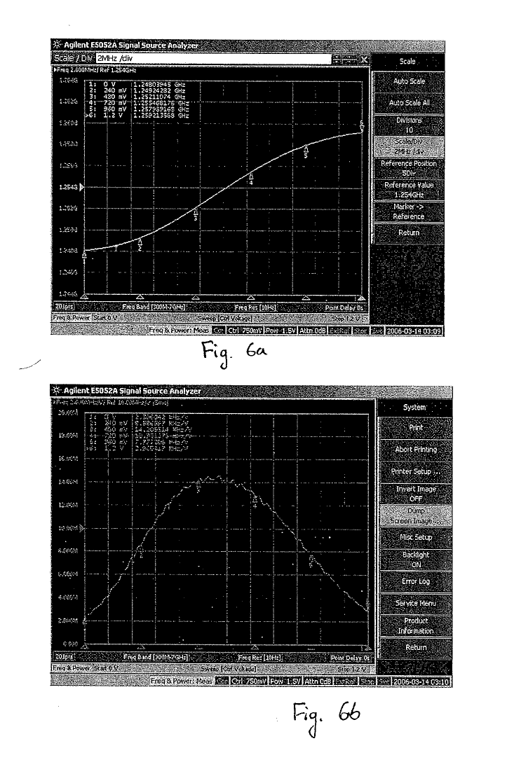

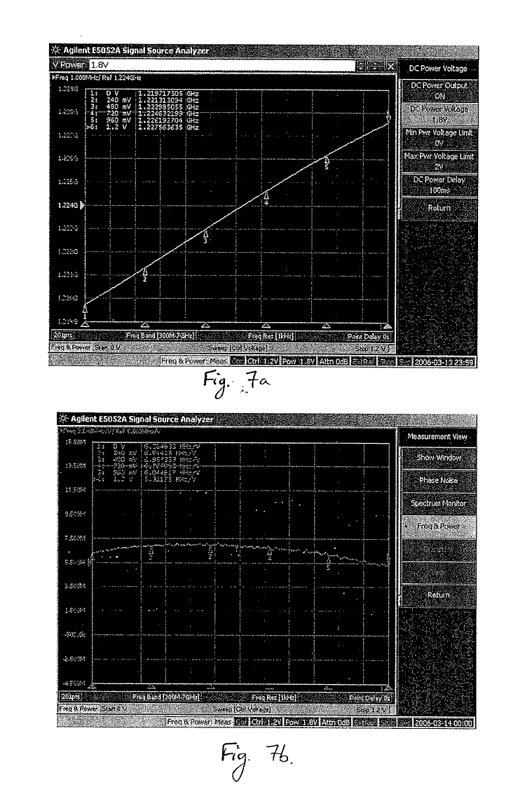

Referring to FIGS. 6a and 6b, there are illustrated measurements taken from a conventional VCO having a single varactor set. FIG. 6a illustrates the frequency curve versus tuning voltage and FIG. 6b illustrates the tuning sensitivity (Kv) curve versus tuning voltage over a range of tuning voltages from zero to 1.2 V. It can be clearly seen in FIG. 6a that the frequency behavior is nonlinear between 1.240 GHz and 1.259 GHz, for the tuning voltage νₜᵤₙₑ between 0 and 1.2V. In contrast, referring to FIG. 7a and FIG. 7b, there are illustrated measurements of a VCO with three varactor sets in parallel, according to an embodiment of the invention. Again, FIG. 7a illustrates the VCO resonant frequency, f_{VCO}, curve versus tuning voltage and FIG. 7b illustrates the tuning sensitivity, Kv, versus tuning voltage. The tuning voltage is again varied over the range from zero to 1.2 V. As can be seen from FIG. 7a, the frequency response of the VCO with three parallel-connected varactor sets is substantially linearized compared to the frequency response of a conventional VCO (see FIG. 6a). Similarly, it can be seen in FIG. 7b that the tuning sensitivity is quite linear over the range of tuning voltages plotted. The measurements shown in FIGS. 6a, 6b, 7a and 7b were taken using an Agilent E5052A signal source analyzer and the VCO's were fabricated using 130 nm CMOS processes. The results presented in FIGS. 7a and 7b illustrate that providing a voltage controlled oscillator with multiple varactor sets coupled in parallel, according to the invention, may significantly linearize the frequency response and tuning sensitivity of the VCO.

Having thus described several aspects and embodiments of the invention, modifications and/or improvements may be apparent to those skilled in the art and are intended to be part of this disclosure. It is to be appreciated that the invention is not limited to the specific examples described herein and that the principles of the invention may be used in a wide variety of applications. The above description is therefore by way of example only, and includes any modifications and improvements that may be apparent to one of skill in the art. The scope of the invention should be determined from proper construction of the appended claims and their equivalents.

What is claimed is:

1. A tunable voltage controlled oscillator comprising:
a first varactor set comprising at least one CMOS varactor;
a second varactor set comprising at least one CMOS varactor and coupled in parallel with the first varactor set;
a first bias voltage applied to the first varactor set; and
a second bias voltage applied to the second varactor set;
wherein the first and second bias voltages are selected such that a frequency versus tuning voltage of the voltage controlled oscillator is substantially linear over a selected operating frequency range of the voltage controlled oscillator.

2. The tunable voltage controlled oscillator as claimed in claim 1, wherein the CMOS varactors are accumulation mode MOS capacitors.

3. The tunable voltage controlled oscillator as claimed in claim 1, wherein the CMOS varactors are depletion mode MOS capacitors.

4. The tunable voltage controlled oscillator as claimed in claim 1, wherein the CMOS varactors are reverse-biased pn-junction diodes.

5. The tunable voltage controlled oscillator as claimed in claim 1, further comprising a third varactor set and a third bias voltage applied to the third varactor set; and wherein the first, second and third bias voltages are selected such that the frequency versus tuning voltage of the voltage controlled oscillator is substantially linear over the selected operating frequency range of the voltage controlled oscillator.

6. A method of linearizing a frequency versus tuning voltage response of a voltage controlled oscillator comprising a first varactor set and a second varactor set, the method comprising acts of:
providing the first varactor set with a first bias voltage;
providing the second varactor set with a second bias voltage; and
adjusting the first and second bias voltages so as to linearize the frequency versus tuning voltage response of the voltage controlled oscillator over a selected operating frequency range of the voltage controlled oscillator.

7. The method as claimed in claim 6, further comprising an act of providing the first and second varactor sets with a common tuning voltage.

8. The method as claimed in claim 6, wherein the voltage controlled oscillator further includes a third varactor set, and further comprising providing a third bias voltage to the third varactor set;
wherein the act of adjusting includes adjusting the first, second and third bias voltages so as to linearize the frequency versus tuning voltage of the voltage controlled oscillator over the selected operating frequency range of the voltage controlled oscillator.

9. The method as claimed in claim 8, wherein the act of adjusting includes adjusting the first, second and third bias voltages such that the frequency versus tuning voltage response of the voltage controlled oscillator is substantially linear over the selected operating frequency range of the voltage controlled oscillator.

10. A voltage controlled oscillator comprising:
a tunable resonant circuit including at least one inductor, a first set of varactors and a second set of varactors, the first and second sets of varactors being connected in parallel with one another;
a tuning port constructed and arranged to receive a tuning voltage;
a first port coupled to the first varactor set and constructed and arranged to receive a first bias voltage; and
a second port coupled to the second varactor set and constructed and arranged to receive a second bias voltage;
wherein the first and second bias voltages are selected such that an operating frequency of the voltage controlled oscillator changes in a substantially linear manner in response to changes in the tuning voltage.

11. The voltage controlled oscillator as claimed in claim 10, wherein the first set of varactors includes at least one CMOS accumulation mode or depletion mode capacitor; and wherein the second set of varactors includes at least one CMOS accumulation mode or depletion mode capacitor.
